(19) United States
(12) Patent Application Publication
(10) Pub. No.: US 2010/0044822 A1
(43) Pub. Date: Feb. 25, 2010

(54) LUMINOUS RADIATION COLOUR PHOTOSENSITIVE STRUCTURE

(75) Inventors: Antonio Longoni, Milano (IT); Federico Zaraga, Milano (IT); Giacomo Langfelder, Milano (IT)

Correspondence Address: Husch Blackwell Sanders, LLP;Husch Blackwell Sanders LLP Welsh & Katz, 120 S RIVERSIDE PLAZA, 22ND FLOOR, CHICAGO, IL, 60606, US

(73) Assignee: Politecnico di Milano, Milano (IT)

(21) Appl. No.: 12/518,265

(22) PCT Filed: Dec. 5, 2007
(86) PCT No.: PCT/IB07/03906

§ 371 Date: Jun. 24, 2009

(30) Foreign Application Priority Data
Dec. 6, 2006 (IT) MI2006A002352

(51) Int. Cl. H01L 27/146

(52) U.S. Cl. 257/446; 257/E27.133

(57) ABSTRACT

There is described a structure which is photosensitive to the colour of a light radiation; said structure being formed by a semiconductor substrate having a first type of conductivity and the substrate is adapted to generate a different distribution of carriers upon incidence of a light radiation as the depth varies as a function of the at least one wave length of the light radiation. The structure comprises at least one first and one second element, both arranged in the substrate and adapted to collect the generated carriers; both the first and second element being adapted to generate first and second electrical signals as a response to the amount of collected carriers. The structure comprises means adapted to generate an electrical field orthogonal to the upper surface of the substrate and further means adapted to generate an electrical field transversal to the structure and parallel to its upper surface: said means in combination with said further means are adapted to generate a resulting electrical field such as to determine different trajectories for the carriers within the substrate as a function of the at least one wave length of the incident light radiation. The trajectories are directed towards the first element or towards the second element.

The present invention relates to a structure which is photosensitive to the colour of a light radiation.

Photosensitive sensors which may be used for digital cameras are known in the state of the art. In such cameras, an image of the item is formed by means of a photographic objective on a plane where, instead of the film of traditional “analog” systems, there is a sensor, for instance a CMOS or CCD (Charge Coupled Devices) type sensor, formed by an array of photosensitive elements. The phenomenon resulting from the sensor being hit by light is the generation of electron-hole pairs in an amount proportional to the number of photons incident on each photosensitive element. The array detector therefore provides information related to the spatial distribution of the intensity of the radiation received by the objective. In this manner, though, it would only allow the generation of a black and white image without providing any information relating to the colour of the photographed item.

The most common solution for the capture of colour images is to place a mask designated CFA (Colour Filter Array) in front of the sensor, the mask having a coloured filter for each individual pixel. There are various masks which differ from one another because of the spectrum transmission of the filters and the spatial distribution thereof (pattern). Three colours are usually used: either the red, green and blue based colours (RGB filter) or the complementary cyano, magenta and yellow colours (CMY). The most frequently used arrangement consists in the Bayer mask (from the name of a researcher from Kodak) which has twice the number of green filters with respect to red and blue ones. There is currently an interest in multi-colour filters, of which many options have been suggested.

The colour information captured with CFAs is incomplete as only one of the base colours is captured for each pixel in this manner. The other colour information which has not been measured needs to be reconstructed by processing the information derived from the other adjacent pixels. However, this interpolation operation, designated “demosaicing”, decreases the quality of the image.

Several are the drawbacks due to the use of CFAs. In the process of manufacturing of the sensor a relatively expensive additional step is required in the process, during which the filters are deposited and the same filters are made of relatively expensive materials. In the image acquisition, the interpolation on the camera for the computing of the colour requires the execution of specific algorithms within the camera. In terms of the quality of the image, the interpolation sometimes produces artefacts in the image and approximates the colour and decreases the resolution.

A different solution is to overlap two or more sensors so as to detect only or mainly one part of the visible spectrum with each sensor, exploiting the known dependence of the absorption coefficient of the semiconductors on the wave length.

A photosensitive element sensor is described in U.S. Pat. No. 5,965,875 to Foveon. The sensor of the above said patent exploits the differences in the absorption by silicon of light having different wave lengths for the separation of colours; this allows to directly capture the three colour information for each pixel. In this manner, no subsequent interpolations are required; this makes the spatial resolution higher and comparable to that of a sensor having approximately twice the number of pixels employing a coloured filter mask, and eliminates the artefacts which may be generated by the interpolation algorithms from the image. The Foveon sensor has a special structure, which is equivalent to the structure of three overlapped sensors (actually it is a single complex structure). The operating principle is to distinguish different regions of the spectrum by using the variation in the absorption coefficient of silicon with the wave length of the light. Blue is absorbed on the surface (thus by the first sensor), green is absorbed in an intermediate layer (second sensor) and red is absorbed more in depth. Each of the three sensors therefore provides an independent colour information.

However, the above said sensor displays some drawbacks due to the production of a “vertical” complex structure and due to the fact that the sensor could not be manufactured in a standard CMOS process. Furthermore, the complexity of the structure considerably increases if more than three colours are to be captured.

Another type of sensor is described in US patent 2005/0194653. Said sensor directly captures the colour information of the incident light without the use of absorption filters arranged on the surface. The colour information is a result of a vertical arrangement of at least two junctions for the detection of charges arranged in a silicon substrate and collecting the charges generated by different wave length photons on the basis of different depths.

Another type of sensor is described in US patent 2004/0178464. Said sensor comprises two vertical stacks of photosensitive elements each having a different spectral response and formed on a semiconductor substrate. At least one of the sensors comprises a layer of material other than silicon.

In view of the state of the art, it is the object of the present invention to provide a structure which is photosensitive to the colour of a light radiation which is different from the known ones.

According to the present invention, said object is achieved by a structure which is photosensitive to the colour of a light radiation, said structure being formed by a semiconductor substrate having a first type of conductivity and said light radiation having at least one wave length, said substrate being adapted to generate carriers having a different distribution as the depth varies upon incidence of a light radiation, as a function of the at least one wave length of the light radiation, said structure comprising at least one first and one second element, both arranged in said substrate and adapted to collect the generated carriers, both said first and said second element being adapted to generate at least first and second electrical signals in response to the amount of carriers collected, said structure comprising means adapted to generate an electrical field orthogonal to the upper surface of the substrate, characterised in that it comprises further means adapted to generate an electrical field transversal to the structure and parallel to its upper surface, said means in combination with said further means being adapted to generate a resulting electrical field such as to determine a distribution of trajectories for the carriers within the substrate as a function of the at least one wave length of the incident light radiation, said trajectories being mainly directed towards said first element or towards said second element as a function of the at least one wave length of the incident radiation.

The features and advantages of the present invention will become apparent from the following detailed description of a practical embodiment thereof, shown by way of non-limitative example in the accompanying drawings, in which:

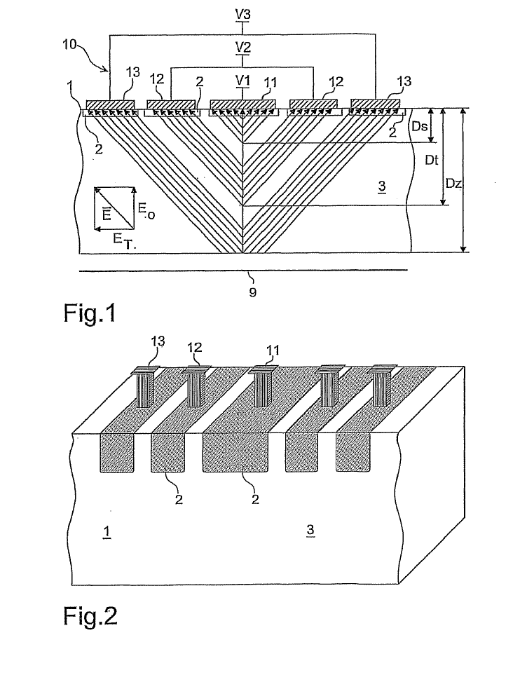

FIG. 1 is a diagram of the structure which is photosensitive to the colour of a light radiation according to the invention;

FIG. 2 is a possible implementation of the photosensitive structure of FIG. 1;

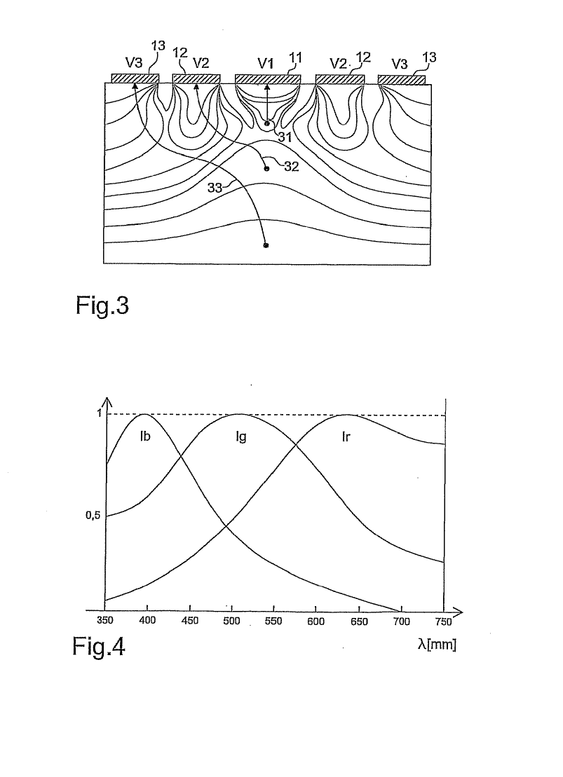

FIG. 3 is a diagram of the equipotential lines for the structure in FIG. 1;

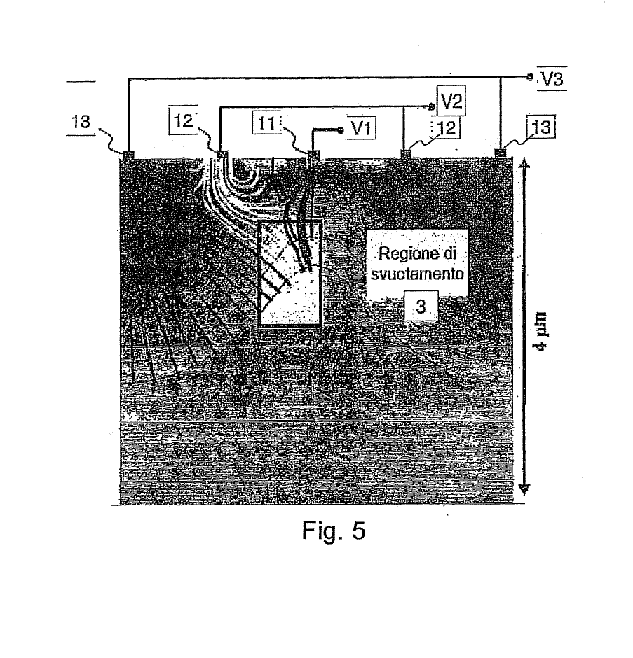

FIG. 4 is a diagram of the spectral responsivity of the structure in FIG. 1 as a function of the wave length.

Referring to FIG. 1, a structure which is photosensitive to a light radiation having different wavelengths is shown in accordance to the present invention. FIG. 1 shows a single pixel of a detector comprised of a two-dimensional array of identical pixels. The single pixel comprises a certain number of pn junctions 2, or as an alternative MOS photogates, or MS (metal-semiconductor) junctions or junctions made by another technology. The pn junctions 2 are formed on a semiconductor substrate 1; the pn junctions may be formed with implantations/diffusions of the n-type in the case of a p-type substrate, or with implantations/diffusions of the p-type in the case of an n-type substrate.

The volume for the generation of the electrical signal due to photons incident on the structure is mainly comprised of a semiconductor region 3, which is totally depleted of carriers by means of the appropriate polarisation of the junctions or photogates, placed beneath the upper surface of the semiconductor.

An appropriate differentiation of the polarisations of the junctions or photogates, having a static and/or dynamic nature, allows to obtain an electric field distribution in the device with significant components parallel to the surface of the structure. Therefore, the structure must include means adapted to generate a transversal electrical field Et, that is, a field parallel to the surface of the single pixel, such means in combination with known means in the sensors adapted to generate an electrical field Eo orthogonal to the surface, allowing to create a resulting electrical field which is inclined by a certain angle with respect to the surface of the structure. In this manner, the carriers generated by the light flux move in the depleted region along trajectories inclined with respect to the surface under the action of the electric field. By placing some collecting electrodes on the upper surface of the sensor, the carriers generated at different depths by photons having a different wave length incident in the same position, reach the surface along different trajectories and are therefore collected by different electrodes.

Preferably, said means comprise an electrode 9 arranged on the lower surface of the photosensitive structure and a plurality 10 of electrodes arranged on the upper surface, the surface adjacent to the pn junction 2, of the single pixel, and having a different value polarisation. In this manner resulting electric fields having different value are generated, leading the carriers generated by different wave length photons to the surface along different trajectories.

Since a different colour corresponds to each photon wave length, a different portion of the chromatic spectrum corresponds to each collecting electrode. Different chromatic components may therefore be discriminated on the basis of the well known dependence of the absorption depth of photons on the wave length. The correspondence between spectral region and carrier collecting electrode may simply be rearranged by changing the polarisation pattern of the electrodes both statically and dynamically. A linear combination of the information obtained from the measurement of the electrical signals provided by the single electrodes allows to obtain the position of the spot which is representative of the colour of the radiation incident in a RGB space. A two-dimensional array of these pixels therefore returns a colour image.

The plurality 10 of electrodes preferably comprises a first electrode 11 arranged in a central position, adjacent to a central region 21 having a different conductivity from the substrate and polarised with a voltage V1, two electrodes 12 specularly arranged with respect to the first electrode 11 and adjacent to two regions 22 having a different conductivity from the substrate and polarised with a voltage V2 which is different from V1, other two electrodes 13 specularly arranged with respect to the first electrode 11 at a greater distance of the electrodes 12 and adjacent to two regions 23 having a different conductivity from the substrate and polarised with a voltage V3 such that V3 is different from V1 and V2. In this manner an RGB sensor may be made, in which the electrode 11 detects the colour blue, the electrodes 12 detect the colour green and the electrodes 13 detect the colour red. Other electrodes displaying other polarisation voltages may be added in order to detect a finer subdivision of the spectrum. The electrode 11 is adapted to collect the carriers which are generated up to a depth Ds, the electrodes 12 are adapted to collect the generated carriers up to a depth Dt and the electrodes 13 are adapted to collect the generated carriers up to a depth Dz. In case of a p-type substrate, V3>22 V1.

FIG. 2 shows a possible implementation of the structure in FIG. 1. Said type of structure is obtained with a CMOS process.

FIG. 3 shows an equipotential line diagram for the structure in FIG. 1. Since the force lines of the electrical field are always in a direction orthogonal to the equipotential lines, the possible carrier trajectories are obtained. Lines 31, 32 and 33 are some of the possible trajectories of the carriers which are separated according to the different generation depth.

FIG. 4 shows a diagram of the spectral responsivity of the structure in FIG. 1 as a function of the wave length λ of the incident radiation. The information on the spectral content of the incident radiation are in the form of electrical signals; a specific output signal amplitude will correspond to each contact as the colour of the incident light varies, for instance a photocurrent such as photocurrents Ib, Ig and Ir of the present diagram.

The main advantages of the present invention lie in that, in terms of image quality for each pixel, there are directly three or more independent items of information on the spectral composition and no spatial interpolation algorithms are required among pixels, nor are there approximations and/or artefacts on the spectral components of the incident light.

No additional step of the process in which the coloured filters are deposited as in the known art is required in the production step of the structure and furthermore there may be implementations of the invention in a standard CMOS technology, even though specifically optimised processes may be developed for this device.

The continuous scaling of the CMOS technology will allow to discriminate an increasing number of chromatic components, the size of pixels being the same.

1-11. (canceled)

12. A structure which is photosensitive to a light radiation, said structure comprising a semiconductor substrate and said light radiation having at least one wavelength, said substrate being suitable to generate carriers as the absorption depth varies as a function of the at least one wavelength of the light radiation, said structure comprising a first and a second element, both arranged in said substrate and adapted to collect the generated carriers, said first and said second element being both adapted to generate at least first and second electrical signals in response to the amount of collected carriers, said structure comprising’ means adapted to generate an electrical field substantially orthogonal to the surface of the substrate,
wherein the semiconductor substrate includes a semiconductor region having a single first type of conductivity for generating the carriers,
wherein the semiconductor region is configured so that it's adapted to generate the carriers corresponding to different wavelengths at different depths of the semiconductor region,
characterized in that the structure comprises further means adapted to generate an electrical field within the semiconductor region with significant components parallel to the surface of the structure, said means in combination with said further means being adapted to generate a resulting electrical field in order to determine a distribution of trajectories for the carriers within the semiconductor region, said trajectories being mainly directed towards said first element or towards said second element as a function of the at least one wavelength of the incident light radiation, wherein the resulting electrical field is inclined respect to the surface of the structure, so that the trajectories for the carriers within the semiconductor region are inclined respect to the surface of the structure.

13. A structure according to claim 12, wherein the first element is a first electrode and the second element is a second electrode, the first electrode being electrically isolated from the second electrode.

14. A structure according to claims 12, wherein the distance between the position of the first element and a lower surface of the semiconductor region is substantially equal to the distance between the position of the second element and the lower surface of the semiconductor region.

15. A structure according to claim 12, characterised in that said first and second elements are arranged near the surface of the semiconductor substrate.

16. A structure according to claim 15, characterised in that said first and second elements comprise regions having a second type of conductivity such as to form pn junctions with the semiconductor region.

17. A structure according to claim 12, characterised in that said first and second elements comprise photogates.

18. A structure according to claim 13, wherein said first and second electrodes are in contact with a first and a second pn junction, said first and second electrode being polarised
with a first voltage and a second voltage having different value to create potential differences which are different from one another and with a further electrode arranged in contact with the lower surface of the substrate and polarised with a reference voltage.

19. A structure according to claim 18, characterised in that said second pn junction comprises two elements which are specularly arranged with respect to the first pn junction and said second electrode comprises two separate electrodes specularly arranged with respect to said first electrode.

20. A structure according to claim 12, wherein the carriers are generated at the different depths by the light radiation incident in substantially the same position.

21. A structure according to claim 12, wherein the further means are further adapted to change dynamically the resulting electrical field.

22. A structure according to claim 21, characterised in that said semiconductor substrate is of the p-type and said second voltage has a value higher than said first voltage.

23. A structure according to claim 12, wherein the semiconductor region adapted to generate the carriers is a depleted region.

24. A structure according to claim 12, the structure further comprising a third element adapted to generate third electrical signals in response to the amount of collected carriers, wherein said trajectories are mainly directed towards said first, second or third element as a function of the at least one wavelength of the incident light radiation.

25. A two-dimensional array comprising a plurality of photosensitive structures according to claim 12.
